(19) United States
(12) Patent Application Publication
(10) Pub. No.: US 2017/0261306 A1
(43) Pub. Date: Sep. 14, 2017

(54) EXTENSION SENSOR AND REDUCTION OF A DRIFT OF A BRIDGE CIRCUIT CAUSED BY AN EXTENSION

(71) Applicant: Infineon Technologies AG, Neubiberg (DE)

(72) Inventor: Udo AUSSERLECHNER, Villach (AT)

(21) Appl. No.: 15/451,771

(22) Filed: Mar. 7, 2017

(30) Foreign Application Priority Data
Mar. 9, 2016 (DE) 102016104306.0

(51) Int. Cl. G01B 7/16; G01R 17/02; G01R 33/09

(52) U.S. Cl. CPC G01B 7/18; G01R 33/09; G01R 17/02

(57) ABSTRACT

A circuit comprise a semiconductor substrate of an integrated circuit, comprising at least two resistors arranged in different orientations in, on or at the semiconductor substrate. The resistance value of the respective one of the resistors is substantially independent of an acting magnetic field. An output signal is determinable on the basis of a comparison of the resistance values of the resistors. Moreover, a circuit comprising a bridge circuit is specified, wherein the bridge circuit comprises at least two MR elements arranged on, at or in a substrate, comprising an extension sensor which provides a signal on the basis of a difference in mechanical extensions in two different directions parallel to a plane in which the two MR elements lie, wherein the circuit is configured to combine an output signal of the bridge circuit by means of the signal.

### RELATED APPLICATION

This application claims priority under 35 U.S.C. §119 to German Patent Application No. 102016104306.0, filed on Mar. 9, 2016, the content of which is incorporated by reference herein in its entirety.

### TECHNICAL FIELD

The invention relates to a circuit for an extension sensor, and to a circuit for reducing a drift of a bridge circuit caused by an extension. Moreover, corresponding methods are specified.

### BACKGROUND

A disadvantage is, in particular, that the magnetic field sensor is not independent of the mechanical strain and that an output signal of a bridge circuit is not independent of the mechanical strain.

### SUMMARY

An object of the invention is to avoid the disadvantages mentioned above and, in particular, to present a suitable improvement.

This object is achieved in accordance with the features of the independent patent claims. Developments of the invention are also evident from the dependent claims.

In order to achieve the object, a circuit is specified
comprising a semiconductor substrate of an integrated circuit,
comprising at least two resistors arranged in different orientations in, on or at the semiconductor substrate,
wherein the resistance value of the respective resistor of the at least two resistors is substantially independent of an acting magnetic field,
wherein an output signal is determinable on the basis of a comparison of the resistance values of the at least two resistors,
wherein each of the two resistors experiences a greater change in resistance on account of a change in geometry than on account of a change in the specific electrical resistance on the occasion of an extension in the current flow direction.

In one development, the at least two resistors are composed of a nonmagnetic material.

In one development, the circuit is used for ascertaining an extension of the semiconductor substrate.

In one development, the circuit carries out measurement for ascertaining a difference in extension of the semiconductor substrate in two directions.

In one development, the at least two resistors are arranged as a half-bridge circuit.

In one development, the different orientations have a predefined angle not equal to 0 degrees.

In one development, the predefined angle is approximately one of the following angles: 22.5 degrees, 45 degrees, 67.5 degrees, 90 degrees.

By way of example, the predefined angle may be an angle different than 0 degrees which is e.g., substantially a multiple of 22.5 degrees.

In one development, the circuit has four resistors arranged as a full-bridge circuit.

In one development,
a first series circuit comprises a first resistor and a second resistor,
a second series circuit comprises a third resistor and a fourth resistor,
the first series circuit is arranged in parallel with the second series circuit,
the first resistor and the fourth resistor are arranged in a diagonal of the bridge circuit comprising the first and second series circuits, and wherein the second resistor and the third resistor are arranged in a diagonal of the bridge circuit,
the first resistor and the fourth resistor have a first orientation, and
the second resistor and the third resistor have a second orientation,
wherein the first orientation is different than the second orientation.

In one development, the at least two resistors comprise a material of an interconnect plane of an integrated circuit technology.

In one development, the at least two resistors substantially comprise one of the following materials: aluminum, copper.

In one development, the circuit is used for offset compensation of a magnetoresistive sensor.

In particular, the circuit is arranged as an extension sensor in direct spatial proximity to the magnetoresistive sensor.

Furthermore, an arrangement is provided comprising the circuit described above here and a magnetoresistive sensor,
wherein the circuit and the magnetoresistive sensor are arranged in direct spatial proximity to one another,
wherein the magnetoresistive sensor has a bridge circuit comprising at least two magnetoresistive resistors,
wherein the at least two resistors of the circuit and the at least two magnetoresistive resistors of the magnetoresistive sensor in each case have a known resistance-specific temperature coefficient.

In one development, the at least two resistors of the circuit and the at least two magnetoresistive resistors of the magnetoresistive sensor in each case have a substantially identical resistance-specific temperature coefficient.

In one development, the respective magnetoresistive resistor is an AMR resistor, in particular an AMR strong field sensor.

A method for measuring an extension is proposed
by means of a circuit
comprising a semiconductor substrate of an integrated circuit,
comprising at least two resistors arranged in different orientations in, on or at the semiconductor substrate,
wherein the resistance value of the respective resistor of the at least two resistors is substantially independent of an acting magnetic field,
comprising the following step:
determining an output signal on the basis of a comparison of the resistance values of the at least two resistors, wherein each of the two resistors experiences a greater change in resistance on account of a change in geometry than on account of a change in the specific electrical resistance on the occasion of an extension in the current flow direction.

Moreover, in order to achieve the object, a circuit is specified
comprising a bridge circuit, wherein the bridge circuit comprises at least two MR elements arranged on, at or in a substrate,
comprising an extension sensor which provides a signal on the basis of a difference in mechanical extensions in two different directions parallel to a plane in which the two MR elements lie,
wherein the circuit is configured to combine an output signal of the bridge circuit by means of the signal.

Combining the output signal of the bridge circuit with the signal of the extension sensor makes it possible to reduce, in particular (at least partly) to compensate for, the offset drift of the bridge circuit.

The extension sensor comprises for example a first resistive element and a second resistive element, wherein the first resistive element and the second resistive element are arranged at a predefined angle with respect to one another, and wherein the first resistive element and the second resistive element are embodied from a nonmagnetic metal.

By way of example, the nonmagnetic metal has a specific sheet resistance of less than 10 ohms.

Optionally, the extension sensor may also be embodied as a bridge circuit, wherein a respective element of the bridge circuit may be arranged in particular spatially adjacent to a respective MR element. In particular, per string of the bridge circuit, the current flow direction in the two sensor elements assigned to the MR elements is parallel or in antiparallel with the MR elements (the sign of the current is unimportant).

The bridge circuit of the MR elements may be a half-bridge circuit or a full-bridge circuit. In particular, in one option, the MR elements are AMR elements.

In one development, the extension sensor is a strain sensor or comprises a strain sensor.

By way of example, the extension sensor may be embodied to detect the extension (strain) of the semiconductor substrate directly, without determining the stress in the process.

In one development, the extension sensor comprises the circuit described above.

In one development, the extension sensor comprises a stress sensor, wherein the mechanical extension of the substrate is determinable on the basis of an output signal of the stress sensor.

By way of example, the extension (strain) may be determined on the basis of the stress by means of Hooke's law or on the basis of Hooke's law, which is correspondingly applied to a more complex overall structure (e.g., laminate).

In one development, the output signal of the bridge circuit is combined by means of the signal by both signals being added or subtracted.

By way of example, the resistors of the extension sensor (also referred to as “strain resistors”) may be arranged in a manner rotated by 90°; in this case, the sign of the signal of the strain sensor may be inverted and this inverted signal may be added to the output signal of the bridge circuit.

In this case, it should be noted that a combination, e.g., in the form of the addition or subtraction, of the signals may be effected in the form of digitalized signals or analog signals.

In one development, the signal is normalized to the output signal of the bridge circuit by the bridge circuit and the extension sensor being operated with the same supply voltage.

In particular, in one option, both signals are proportional to the supply voltage.

In one development, dominant current flow directions of the MR elements are rotated by approximately 22.5 degrees relative to the edges of the substrate.

In this case, the substrate corresponds for example to a chip comprising the semiconductor substrate.

Furthermore, a method is proposed for reducing an offset drift of a bridge circuit,
wherein the bridge circuit comprises at least two MR elements arranged on, at or in a substrate,
wherein an extension sensor is provided which provides a signal on the basis of a difference in mechanical extensions in two different directions parallel to a plane in which the two MR elements lie,
comprising the following step:
combining an output signal of the bridge circuit with the signal provided by the extension sensor.

### BRIEF DESCRIPTION OF THE DRAWINGS

Example embodiments of the invention are illustrated and explained below with reference to the drawings.

In the figures:

FIG. 1 shows an arrangement with AMR sensors which are connected between a supply voltage Vs and ground;

FIG. 2 shows an electrical equivalent circuit diagram of the arrangement from FIG. 1;

FIG. 3 shows an exemplary arrangement comprising a stress sensor, which arrangement determines a strain value from a stress measurement value, said strain value being used for the compensation of an output signal of an AMR bridge circuit;

FIG. 4 shows an exemplary arrangement comprising a plurality of meanders, which here represent resistors by way of example, which are connected between a supply voltage Vs and ground, wherein the resistance value of each meander is substantially independent of an acting magnetic field;

FIG. 5 shows an arrangement that constitutes a combination of AMR sensors (AMR resistors) and meanders (meander-shaped resistors which form the strain sensor); and

FIG. 6 shows by way of example a resistor which is shaped as a meander and has a plurality of individual regions or segments.

### DETAILED DESCRIPTION

A sensor arrangement is proposed which is suitable, for example, for detecting a mechanical strain state of a top side or underside of an integrated electronic circuit (chip).

In this case, the top side of the chip is, in particular, the side on which active components (e.g., transistors) are situated.

Alternatively, in the case of a flip-chip arrangement, the underside may also have active components.

In this case, it should be noted that there is a difference between a mechanical stress and a mechanical strain. Stress is measured in pascals (1 Pa=1 N/m²), whereas strain is dimensionless. Stress and strain can be converted into one another in homogenous material in accordance with Hooke's law:

Stress=E*strain,

wherein E is a modulus of elasticity (referred to as “Young's modulus”). By way of example, E for copper is 120 GPa, such that an extension of 10⁻³ generates a stress of 120 MPa.

A housing for microelectronic circuits consists of a plurality of layers of different materials (e.g., semiconductor, conductor, plastic) adhering to one another. Here, too, for the predefined geometry there is a defined relationship between stress and extension, although this relationship is more complex than Hooke's law and includes the moduli of elasticity and thicknesses of all the layers involved.

On the basis of this conversion specification, stress can be measured and converted into the corresponding strain using Hooke's law or an analogous law for arrangements comprising inhomogeneous material layer stacks. However, an accurate measurement of stress in pascals is comparatively difficult, complex and beset by inaccuracies, which would then yield a correspondingly inaccurate value of strain.

In order to improve the accuracy, it would be advantageous to measure strain directly.

One motivation for measuring stress and strain is based e.g., on the fact that a multiplicity of microelectronic components are influenced thereby. This may be illustrated by way of example by means of resistors (however, it is correspondingly applicable to other components, such as MOS transistors, bipolar transistors, diodes, Hall effect sensors (Hall plates and vertical Hall elements) and to magnetoresistive sensors): if a semiconductor strip is bent, the resistance value of a resistor component situated on the semiconductor strip changes. There are two effects, which are superimposed:
during bending, the shape of the resistor component changes,
the specific electrical resistance of the semiconductor material also changes, however.

The first effect is governed purely by geometry and is a consequence of strain; the second effect is known as the piezoresistive effect and is attributed to stress, for example. Stress changes the band structure of the semiconductor, as a result of which primarily the mobility of the charge carriers in the semiconductor material changes, but the intrinsic charge carrier density changes as well. Both are subsumed under the piezoresistive effect.

In the case of MOS transistors there is also a pure change in geometry owing to strain and a change in mobility, which is known as the piezo-MOS effect.

In the case of bipolar transistors, besides the pure change in geometry owing to strain, there is a change in the mobility of the minority charge carriers in the base and in the intrinsic charge carrier density, which is known as the piezo-junction effect.

In the case of Hall sensors, besides the change in geometry, there is a change in the Hall constant; this is also known as the piezo-Hall effect.

In the case of magnetoresistive sensors there is a change in magnetostriction besides the change in geometry.

In most components the piezo effect is one to two orders of magnitude more greatly pronounced than the effects caused by deformation.

There are specific arrangements of components in which the piezo effects largely eliminate one another in total; however, the effect governed by strain remains here. By way of example, two identical, heavily p-doped resistors in monocrystalline {100} silicon can be arranged perpendicular to one another. As a result, the series or parallel connection of both resistors changes only by approximately 1%/GPa. On the other hand, given a stress of 1 GPa, the extension of silicon is already 0.6%. If this extension runs in the longitudinal direction of the resistor, then the width and thickness of the resistor decrease on account of Poisson contraction by in each case approximately ¼th of the longitudinal extension and the resistance changes in accordance with

$$\frac{R - {R}_{0}}{{R}_{0}} = 1 + \frac{dL}{L} - \frac{dW}{W} - \frac{dT}{T} .$$

With a longitudinal extension dL/L=0.6%, a width extension dW/W=−0.6/4% and a thickness extension dT/T=−0.6/4%, it follows that:

$$\frac{dL}{L} - \frac{dW}{W} - \frac{dT}{T} = 0.6 \% + 0.15 \% + 0.15 \% = 0.9 \% .$$

The change in resistance as a result of strain is thus approximately of the same magnitude as the change in resistance as a result of stress.

In the case of AMR sensors (magnetoresistive sensors), magnetostriction can be reduced or (largely) eliminated by a specific choice of the alloy ratio of iron and nickel. In this case what remains is (only) the effect governed by strain on the basis of a change in geometry of the sensor. In the case of bridge circuits of AMR sensors, resistors with a first current direction are arranged in a main diagonal of the bridge circuit, and resistors with a second current direction are arranged in the secondary diagonal of the bridge circuit. By way of example, the second current direction may be perpendicular to the first current direction; alternatively, the angle between the two current directions may be less than 90° and (significantly) greater than 0°.

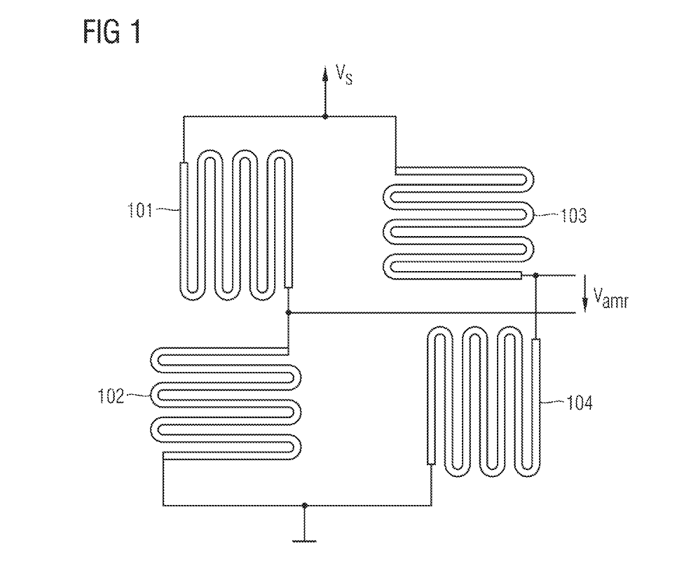

FIG. 1 shows an arrangement with AMR sensors 101 to 104, which are connected between a supply voltage Vs and ground. The AMR sensors 101 and 104 have a first current direction, and the AMR sensors 102 and 103 have a second current direction, wherein in this example the first current direction runs perpendicular to the second current direction. The AMR sensors 101 and 102 are connected in series with one another and the AMR sensors 103 and 104 are connected in series with one another. The series circuit comprising AMR sensor 101 and 102 is arranged in parallel with the series circuit comprising AMR sensor 103 and 104. A voltage Vamr can be tapped off as output signal between the center taps of the series circuits.

The AMR sensors 101 to 104 are illustrated as meanders in FIG. 1, wherein the dominant current direction runs in the longitudinal direction of the paths of the respective meander.

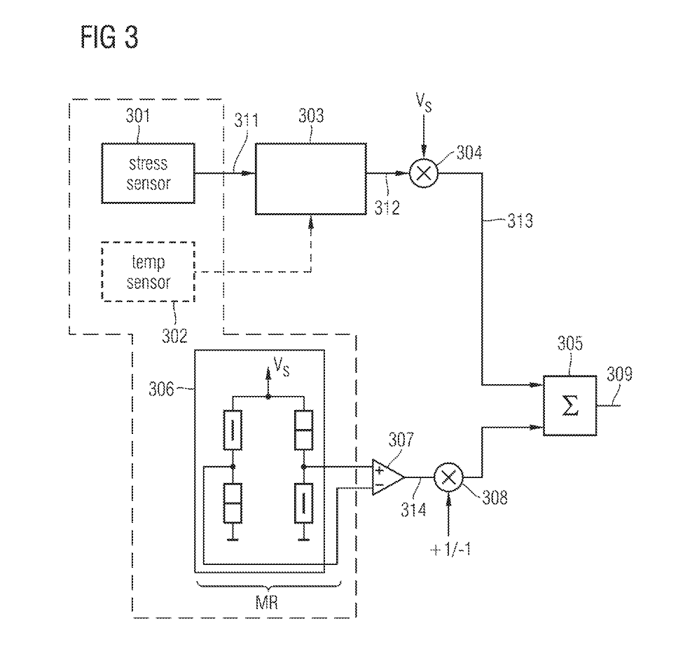

In this case, it should be noted that there are also AMR sensors which do not consist of elongate strips of homogeneous material. By way of example, there are AMR sensors which consist of a multiplicity of round or elliptic disks which are strung together like pearls on a chain: the current thus flows through one disk, then via a short metal connection into the next disk and so on. Moreover, there are AMR sensors in which although the AMR sensor itself is an elongate strip, so-called Barber poles are applied on it. They are metal strips of even better conductivity which bridge the width of the AMR sensor strip at an angle of 45 degrees and constrain the current flow in a direction of 45 degrees with respect to the AMR sensor strip (e.g., FIG. 3 in U.S. Pat. No. 7,592,803 B1).

The AMR sensors 101 to 104 are connected via low-resistance connections in an interconnect plane. An interconnect plane is disclosed for example in U.S. Pat. No. 6,548,396 B2 or in U.S. Pat. No. 5,354,712 A.

FIG. 1 thus shows a so-called Wheatstone bridge which is operated with the supply voltage Vs and provides the voltage Vamr at its output. Said voltage Vamr is dependent on an angle φ of a magnetic field acting on the Wheatstone bridge.

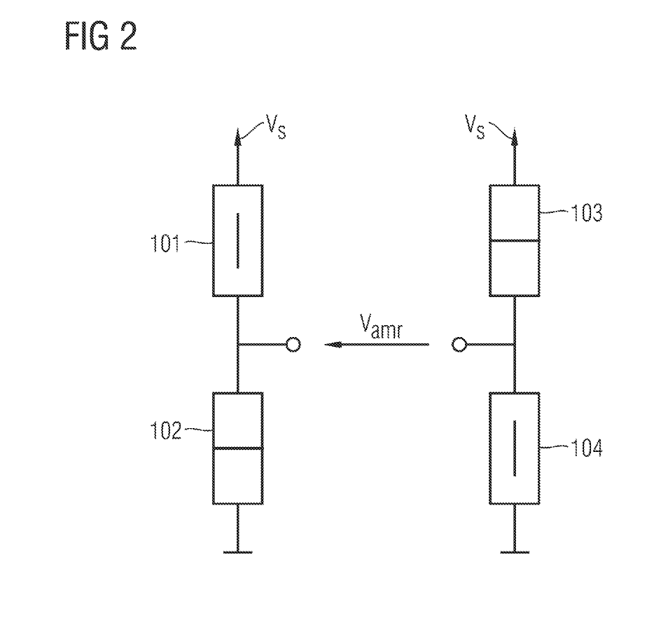

FIG. 2 shows an electrical equivalent circuit diagram of the arrangement from FIG. 1. In the equivalent circuit diagram, the AMR sensors 101 to 104 are shown as resistors (rectangles), wherein a vertical line and a horizontal line in the respective rectangle indicate the primary current flow direction through the AMR sensor.

By way of example, an AMR sensor (which may also be interpreted here as an AMR resistor) may consist of a plurality of elongated strips of permalloy. In this case, permalloy is e.g., a soft-magnetic nickel-iron alloy. A magnetic field applied to the AMR sensor rotates the magnetization of the permalloy in the direction of the magnetic field. Aluminum structures (so-called Barber poles) are situated at the surface of the permalloy, said structures being inclined by approximately 45° relative to the strips and constraining a current flow direction. The resistance of the AMR sensor is thus dependent on the angle between the current flow and the magnetization.

In any case the applied magnetic field results in a detuning of the Wheatstone bridge if the chip with the AMR sensors is bent to a greater extent in one direction than in the other direction. By way of example, in the case of a uniaxial loading state, if e.g., the chip is bent only in the first direction, an increase in the AMR resistance values in the main diagonal and a reduction of the AMR resistance values in the secondary diagonal of the Wheatstone bridge occur. This results in a zero error or offset, that is to say that, for example, without an applied magnetic field or upon averaging over all magnetic field directions, the voltage Vamr is not zero, but rather with greater bending also deviates to a greater extent from zero.

In the case of AMR angle sensors there are two bridge circuits, a sine bridge and a cosine bridge. In the sine bridge, AMR resistors are arranged with first and second directions parallel to the edges of the rectangular chip and, in the cosine bridge, AMR resistors are arranged with first and second directions rotated by 45° with respect to the edges of the rectangular chip. If an extension in the direction of the longitudinal edge of the chip then acts on the chip, that leads to an offset error of the sine bridge, whereas the offset of the cosine bridge is not influenced by this rotation (case 1).

If the two AMR bridges are arranged in a manner rotated by 45°, then the same extension leads to an offset of the cosine bridge, and the offset of the sine bridge remains uninfluenced by the strain governed by the rotation (case 2).

If the two AMR bridges are arranged in a manner rotated by 22.5°, then the extension in the direction of the longitudinal edge of the chip leads to an offset of sine and cosine bridges, wherein the offset is smaller in magnitude than the offset in case 1 or in case 2.

It is known to compensate for a stress, wherein a stress sensor detects the stress and maps it onto a signal (see, e.g., U.S. Pat. No. 6,906,514 or Ausserlechner, Udo, Mario Motz, Michael Holliber: “Compensation of the piezo-Hall effect in integrated Hall sensors on (100)-Si.” Sensors Journal, IEEE 7.11 (2007): 1475-1482).

Such a signal is then combined with a further signal influenced in an undesired manner by the stress, such that a result signal becomes largely independent of the stress. A Hall sensor shall be mentioned as an example, the output signal of said Hall sensor being proportional to an acting magnetic field, but a mechanical stress increases this proportionality figure by approximately +43%/GPa. In the compensation of the stress, the Hall sensor signal is multiplied by

1−EPC·stress

wherein EPC=43%/GPa is chosen. The result thus becomes virtually constant with regard to the mechanical stress.

It is disadvantageous here that a strain compensation cannot be achieved in an efficient manner. In particular, no compensation circuit is known for a bridge offset of AMR sensors that is brought about by strain.

By way of example, the intention is to achieve a reduction or elimination of the effect—brought about by a strain—on a bridge offset of an AMR sensor arrangement.

This can be achieved e.g., by means of a stress sensor by a signal that is provided by the stress sensor being converted into the associated strain, being weighted, multiplied by the supply voltage of the bridge circuit and added to the output signal of the AMR sensor arrangement.

FIG. 3 shows an exemplary arrangement comprising a stress sensor 301, which feeds a stress measurement value 311 to a processing unit 303. The processing unit 303 converts the stress measurement value 311 into a strain value 312. A multiplying unit 304 multiplies the strain value 312 by a supply voltage Vs and provides the result 313 of the multiplication to a first input of an adding unit 305.

The AMR bridge circuit shown in FIG. 1 is illustrated as a block 306 in FIG. 3. The output signal Vamr of the AMR bridge circuit is applied to inputs of an operational amplifier (comparator) 307 and the output signal 314 of the operational amplifier 307 is multiplied by a factor of +1 or a factor of −1 by a multiplying unit 308. The output of the multiplying unit 308 is connected to a second input of the adding unit 305.

The adding unit 305 provides a signal 309 at its output, in which signal the effect of strain on the offset of the AMR bridge has been (substantially) eliminated.

Optionally, a temperature sensor 302 may be provided, which feeds a temperature signal to the processing unit 303, such that the stress measurement value 311 may be converted into the strain value 312 in a manner taking account of the temperature. In this regard, in particular, temperature-dependent changes may be identified and (at least proportionally) compensated for.

By way of example, the stress sensor 301, the temperature sensor 302 and the block 306 may be arranged jointly on a substrate, thereby ensuring a thermal and mechanical coupling.

What is problematic here is that a stress sensor usually supplies an output signal which, although proportional to the acting stress, is not constant over the profile of the temperature. In other words: the proportionality factor changes with temperature. Moreover, it is disadvantageous that the proportionality factor of stress sensors is often subject to considerable component variations. Furthermore, it is problematic that the conversion of stress into strain is not constant in relation to temperature since the modulus of elasticity is also dependent on temperature. Consequently, e.g., the weighting factor would have to be provided with a suitable temperature dependence in order to ensure the compensation in a wide temperature range. For this purpose, e.g., a temperature sensor would be required or a circuit would be necessary which generates a signal with the required (desired) temperature dependence. Both approaches lead to an increased complexity of the circuit.

In order to eliminate the AMR bridge offset, it is possible to detect a difference in strain in first and second directions. If strain is determined from stress, then it should actually be taken into consideration that the two variables are not linked to one another in a scalar manner (via a scalar modulus of elasticity), but rather in a tensorial manner (i.e. the modulus of elasticity becomes a matrix). Consequently, the difference between extensions in a first and a second direction does not arise linearly proportionally to the difference in stresses in the first and second directions, rather the difference arises from a linear combination of a plurality of components of stress. That applies if the material has an anisotropy, as is the case e.g., in the cubic crystal lattice of silicon. If an isotropic material such as amorphous or polycrystalline copper were present, by contrast, it would be possible to determine the difference via the scalar modulus of elasticity.

Consequently, it may be advantageous or necessary to detect a plurality of components of the stress tensor (e.g., both normal stress components σₓₓ and σ_{yy} lying in one plane (“in-plane”), and also the shear stress component σ_{xy} lying in the plane) in order to ascertain therefrom a difference in strain in the first and second directions.

The indirect determination of strain on the basis of stress has the disadvantage that three stress sensors (or stress sensor circuits) for σₓₓ, σ_{yy} and σ_{xy} are required. All these stress sensors have different temperature dependences. Consequently, it would be a significant additional outlay to ascertain the respective temperature dependences and to set them in the circuit in order thus then to be able to carry out an AMR bridge offset compensation in a wide temperature range.

In principle, however, it is advantageous to directly measure strain and/or the difference in strains in the two directions.

This may be achieved, for example, by using a resistor with the following properties or conditions:

(1) The resistor can be oriented in the first direction and the second direction.
(2) The resistor has no or a negligibly small piezo effect.
(3) The resistor has no further direction dependence (that is to say is e.g., not dependent on an angle between the acting magnetic field and the current flow direction, as is the case for an AMR resistor).

A suitable material for such a resistor is metals, e.g., aluminum or copper (if appropriate with small other alloy proportions of a few percent, e.g., of silicon), in particular those which are used in so-called interconnect planes in semiconductor technology.

A circuit may be configured in such a way that it compares these two resistors: without an externally acting extension, both resistors have an equal resistance, for example. If the extension acts predominantly in the first direction, then the resistance with current flow in the first direction increases, while the resistance with current flow in the second direction decreases.

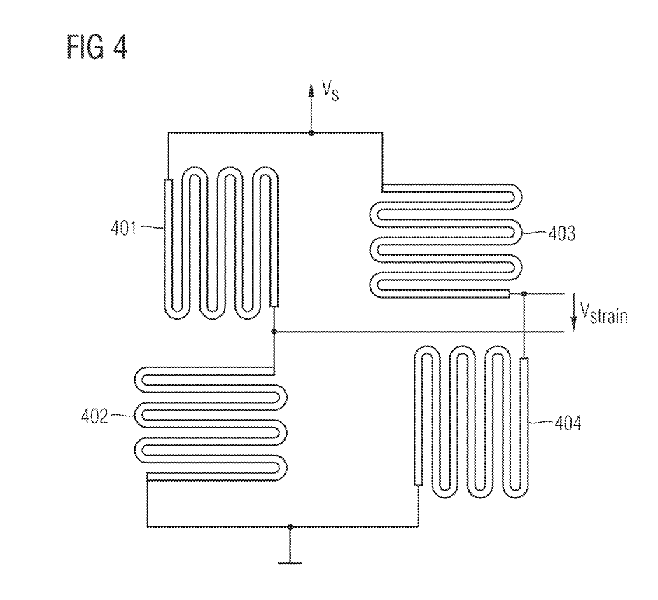

FIG. 4 shows an exemplary arrangement comprising meanders 401 to 404 (which here represent by way of example the resistors mentioned above), which are connected between a supply voltage Vs and ground. The meanders 401 and 404 have a first current direction, and the meanders 402 and 403 have a second current direction, wherein in this example the first current direction runs perpendicular to the second current direction. The meanders 401 and 402 are connected in series with one another and the meanders 403 and 404 are connected in series with one another. The series circuit comprising meander 401 and meander 402 is arranged in parallel with the series circuit comprising meander 403 and meander 404. A voltage Vstrain can be tapped off between the center taps of the series circuits. In this case, this voltage Vstrain directly represents a measure of strain.

In contrast to FIG. 1, the meanders 401 to 404 in FIG. 4 are not composed of permalloy; accordingly, the resistance of the respective meander 401 to 404 is not dependent on an acting magnetic field.

By way of example, the meanders 401 to 404 preferably consist of a metal of the interconnect plane (on account of the low sheet resistance of the interconnect plane, these resistors in practice are extended over a large area). The meanders 401 and 404 are arranged in the main diagonal such that the current flow through these resistors runs in a first direction (that is to say vertically); the meanders 402 and 403 are arranged in the secondary diagonal such that the current flow through these resistors runs in a second direction (that is to say horizontally).

The Wheatstone bridge shown in FIG. 4 may be operated with a supply voltage Vs that is identical or (linearly) proportional to the supply voltage of the AMR sensor bridge from FIG. 1.

The voltage Vstrain as output signal is proportional to the difference in the extensions in both directions (i.e. first direction and second direction). If the arrangement from FIG. 4 is extended in the vertical direction, then the resistors in the main diagonal are enlarged and the strain ascertained increases.

Both in the case of the direct measurement of the extension of the AMR resistors and in the case of the indirect measurement via stress, it is advantageous if the stress or strain sensor is positioned near the AMR resistors in order to experience the same extension (strain) as the AMR resistor itself.

The AMR resistors are comparatively large in terms of their geometrical extent. Therefore, an optional configuration involves also taking account of temperature changes (that is to say a temperature gradient over the extent of the AMR resistor).

If a stress sensor or a strain sensor is used to detect the strain of the AMR resistors, then the stress or strain sensor advantageously covers (approximately) the same sized region as the AMR resistor. It is then possible that the temperature is not the same for the entire region and an output signal is thus already generated solely as a result of the inhomogeneous temperature over the region. This correspondingly leads to a measurement error.

If the aim, then, is for the stress or strain sensor to detect the strain of the AMR resistors as accurately as possible, it is advantageous if the resistor material of the stress or strain sensor has the smallest possible temperature coefficient of resistance (TCR).

A combined compensation of strain and inhomogeneous temperature effects on the bridge circuit comprising AMR resistors can be achieved if the strain sensor consists of a material having the same TCR as the TCR of the AMR resistors.

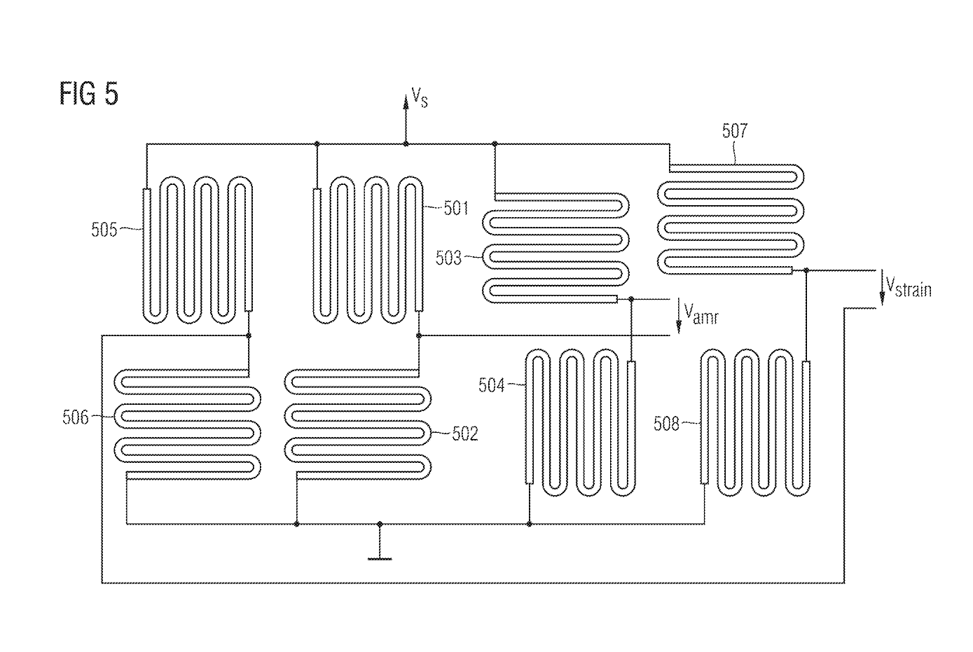

FIG. 5 shows a combination of AMR sensors 501 to 504 (AMR resistors) and meanders 505 to 508. In this case, the meanders 505 to 508 represent the strain sensor.

The arrangement of the AMR sensors 501 to 504 corresponds to the arrangement shown in FIG. 1: the AMR sensors 501 to 504 are connected between a supply voltage Vs and ground. The AMR sensors 501 and 504 have a first current direction, and the AMR sensors 502 and 503 have a second current direction, wherein in this example the first current direction runs perpendicular to the second current direction. The AMR sensors 501 and 502 are connected in series with one another and the AMR sensors 503 and 504 are connected in series with one another. The series circuit comprising AMR sensor 501 and 502 is arranged in parallel with the series circuit comprising AMR sensor 503 and 504.

Consequently, the AMR sensors 501 to 504 represent an AMR bridge with a current flow in the vertical direction in the main diagonal of the bridge and a current flow in the horizontal direction in the secondary diagonal of the bridge. A voltage Vamr can be tapped off as (AMR) output signal between the center taps of the series circuits of the AMR sensors.

The meanders 505 to 508 (resistors) of the strain sensor are grouped around the AMR bridge. Consequently, in this example, a meander of the strain sensor is arranged adjacent to each AMR sensor. The meander 505 is connected in series with the meander 506, and the meander 507 is connected in series with the meander 508. The meander 505 is arranged adjacent to the AMR sensor 501, the meander 506 is arranged adjacent to the AMR sensor 502, the meander 507 is arranged adjacent to the AMR sensor 503, and the meander 508 is arranged adjacent to the AMR sensor 504. In this case, the respective meander 505 to 508 each have the same current direction as the AMR sensors 501 to 504 adjacent thereto. A voltage Vstrain can be tapped off as (strain) output signal between the center taps of the series circuits of the meanders.

The meanders 505 to 508 consist of an aluminum wiring, for example.

Both the meanders 505 to 508 and the AMR sensors 501 to 504 have a meander-shaped structure. In this case, the meander structures may be embodied similarly or differently. In particular, it is an option to vary the number of respective meander paths and/or the number of meanders and/or AMR sensors. In one exemplary embodiment, an identical number of AMR sensors and meanders of the strain sensor may be provided, as is shown in FIG. 5. This produces, for example, (approximately) identical current flow proportions in the vertical and horizontal directions for the AMR sensors and also the meanders of the strain sensor.

Both the AMR bridge and the bridge of the strain sensor are supplied with the supply voltage Vs; the changes in output voltage of the two bridges on account of strain and temperature are thus synchronous.

If, by way of example, the arrangement in accordance with FIG. 5 is extended in the vertical direction, then the resistances of the main diagonal increase in both bridges, such that the voltage Vamr increases and the voltage Vstrain also increases. If the two voltages Vamr and Vstrain are subtracted from one another, then the proportions caused by extension cancel one another out in the result of the subtraction.

If, by way of example, in the arrangement shown in FIG. 5, an increased temperature occurs at the bottom left (e.g., as a result of inherent heating of further circuit sections not shown in FIG. 5), then (in the case of a positive temperature coefficient) the resistance value of the affected bridge elements increases, which causes a negative offset in the bridge output signal Vamr of the AMR bridge. At the same time, however, the increased temperature also leads to a negative offset in the bridge output signal Vstrain of the strain sensor. If the two bridges are operated with the same supply voltage Vs and the resistor materials have the same temperature coefficient, then the offsets of both bridges caused by inhomogeneous temperature cancel one another out upon the subtraction of the output signals Vamr-Vstrain.

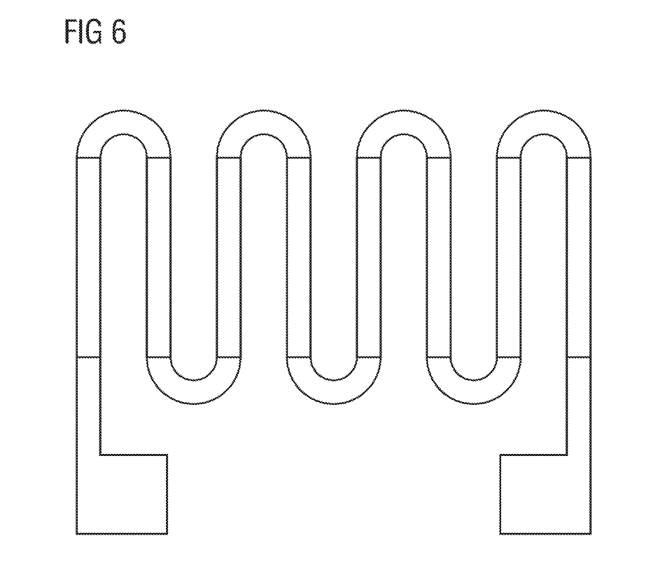

By way of example, each individual resistor or meander of the strain sensor may be embodied as a rectangular region (in plan view, i.e. in the layout). Furthermore, in one option, said resistor is also embodied as a series circuit formed by many of such regions, wherein the individual regions may consist of different materials and in their combination may produce a suitable temperature coefficient. The resistor may be shaped in particular (at least partly) in the form of a meander in which a current direction is dominant. FIG. 6 shows by way of example a resistor shaped as a meander and having a plurality of individual regions or segments. The resistor in FIG. 6 has a (dominant) vertical current direction in relation to the plane of the drawing.

For the strain sensor, a bridge circuit (Wheatstone bridge or full bridge) has been shown as an exemplary embodiment. Every Wheatstone bridge consists of two half-bridges. Furthermore, a half-bridge is also usable as a sensor element. In this case, e.g., the output signal at the center tap of the half-bridge circuit can be compared with a reference voltage.

Another alternative is for the circuit to comprise an ohmmeter that measures the value of two differently oriented resistors and compares the resistance values thereof. Such a comparison may be effected e.g., by means of a subtraction.

Moreover, in one option, an operational amplifier is used, the gain factor of which is determined by the two resistors. If the operational amplifier obtains a predetermined (defined) input voltage, then the output voltage is proportional to said input voltage. If the extension changes the ratio of the two resistors, then the output voltage changes as well. The extension can thus be deduced from the change in the output voltage.

A further option consists in using a respective resistor to generate a current in a feedback circuit. Accordingly, two currents can be generated e.g., with two resistors. The extension can again be deduced by means of a comparison of these two currents. Such a circuit may be realized e.g., in a PTAT circuit for a bandgap voltage reference (see e.g., https://en.wikipedia.org/wiki/Bandgap_voltage_reference) in that case there is a parallel connection of a Ube (that is to say a path along which a base-emitter voltage is dropped) and a further Ube path with a resistor. One of the two strain resistors can respectively be used as resistor.

### The Resistors of the Strain Sensor

The strain sensor comprises, for example, a plurality of resistors, wherein the resistors may be embodied in particular in a meander-shaped fashion.

Optionally, the wiring plane (interconnect layer) of CMOS/BiCMOS/bipolar technology may be used for the resistors of the strain sensor.

Said wiring plane may comprise e.g., aluminum or copper or consist more or less exclusively of these materials. In particular, in addition to aluminum or copper, small amounts of other materials may be present in order, if appropriate, to further improve diverse properties of the wiring plane.

By way of example, a contact of different planes of the wiring and also to other components may be achieved via tungsten plugs, the resistance proportion of which, however, may be negligible with regard to the total resistance.

### The AMR Sensors

By way of example, AMR resistor bridges may be compensated for. In one option, AMR resistors are used as half-bridges, as full bridges, as feedback resistors of amplifiers or as PTAT voltage references. In particular, at least two AMR resistors with different current flow directions are used in these examples. Such an arrangement of AMR sensors may be compensated for with the extension sensor.

It is furthermore possible for other MR resistors, e.g., GMR or TMR resistors, to be used (see e.g., https://de.wikipedia.org/wiki/Magnetoresistiver_Effekt).

By way of example, the current flow directions can also be made different in GMR or TMR resistors. The offset compensation thus functions in accordance with the AMR resistors explained here.

Although the invention has been more specifically illustrated and described in detail by means of the at least one exemplary embodiment shown, nevertheless the invention is not restricted thereto and other variations can be derived therefrom by the person skilled in the art, without departing from the scope of protection of the invention.

1. A circuit comprising:
a semiconductor substrate of an integrated circuit, and
comprising at least two resistors arranged in different orientations in, on or at the semiconductor substrate,
wherein a resistance value of a respective resistor of the at least two resistors is substantially independent of an acting magnetic field,
wherein an output signal is determinable on a basis of a comparison of the resistance values of the at least two resistors,
wherein each of the at least two resistors experiences a greater change in resistance on account of a change in geometry than on account of a change in a specific electrical resistance on an occasion of an extension in a current flow direction.

2. The circuit as claimed in claim 1, wherein the at least two resistors are composed of a nonmagnetic material.

3. The circuit as claimed in claim 1, wherein the circuit is used for ascertaining an extension of the semiconductor substrate.

4. The circuit as claimed in claim 1, wherein the circuit carries out measurement for ascertaining a difference in extension of the semiconductor substrate in two directions.

5. The circuit as claimed in claim 1, wherein the at least two resistors are arranged as a half-bridge circuit.

6. The circuit as claimed in claim 1, wherein the different orientations have a predefined angle not equal to 0 degrees.

7. The circuit as claimed in claim 6, wherein the predefined angle is approximately one of the following angles: 22.5 degrees, 45 degrees, 67.5 degrees, or 90 degrees.

8. The circuit as claimed in claim 1, comprising four resistors arranged as a full-bridge circuit.

9. The circuit as claimed in claim 8,
wherein a first series circuit comprises a first resistor and a second resistor,
wherein a second series circuit comprises a third resistor and a fourth resistor,
wherein the first series circuit is arranged in parallel with the second series circuit,
wherein the first resistor and the fourth resistor are arranged in a diagonal of the full-bridge circuit comprising the first series circuit and the second series circuit, and wherein the second resistor and the third resistor are arranged in a diagonal of the full-bridge circuit,
wherein the first resistor and the fourth resistor have a first orientation, and
wherein the second resistor and the third resistor have a second orientation,
wherein the first orientation is different than the second orientation.

10. The circuit as claimed in claim 1, wherein the at least two resistors comprise a material of an interconnect plane of an integrated circuit technology.

11. The circuit as claimed in claim 1, wherein the at least two resistors substantially comprise one of aluminum or copper.

12. The circuit as claimed in claim 1, wherein the circuit is configured for offset compensation of a magnetoresistive sensor.

13. An arrangement comprising the circuit as claimed in claim 1 and a magnetoresistive sensor,
wherein the circuit and the magnetoresistive sensor are arranged in direct spatial proximity to one another,
wherein the magnetoresistive sensor has a bridge circuit comprising at least two magnetoresistive resistors,
wherein at least two resistors of the circuit and the at least two magnetoresistive resistors of the magnetoresistive sensor have a known resistance-specific temperature coefficient.

14. The arrangement as claimed in claim 13, wherein the at least two resistors of the circuit and the at least two magnetoresistive resistors of the magnetoresistive sensor have a substantially identical resistance-specific temperature coefficient.

15. The arrangement as claimed in claim 13, wherein one of the at least two magnetoresistive resistors is an AMR resistor, in particular an AMR strong field sensor.

16. A method for measuring an extension using a circuit comprising a semiconductor substrate of an integrated circuit, and at least two resistors arranged in different orientations in, on or at the semiconductor substrate, wherein a resistance value of a respective resistor of the at least two resistors is substantially independent of an acting magnetic field, the method comprising:
performing a comparison of the resistance values of the at least two resistors; and
determining an output signal on a basis of the comparison of the resistance values of the at least two resistors,
wherein each of the at least two resistors experiences a greater change in resistance on account of a change in geometry than on account of a change in a specific electrical resistance on an occasion of an extension in a current flow direction.

17. A circuit, comprising:
a bridge circuit, wherein the bridge circuit comprises at least two MR elements arranged on, at or in a substrate, and
an extension sensor which provides a signal on a basis of a difference in mechanical extensions in two different directions parallel to a plane in which the at least two MR elements lie,
wherein the circuit is configured to combine an output signal of the bridge circuit based on the signal.

18. The circuit as claimed in claim 17, wherein the extension sensor is a strain sensor or comprises a strain sensor.

19. The circuit as claimed in claim 17, wherein the extension sensor comprises a circuit comprising:
a semiconductor substrate of an integrated circuit, and
at least two resistors arranged in different orientations in, on or at the semiconductor substrate,
wherein a resistance value of a respective resistor of the at least two resistors is substantially independent of an acting magnetic field,
wherein an output signal is determinable on a basis of a comparison of the resistance values of the at least two resistors,
wherein each of the at least two resistors experiences a greater change in resistance on account of a change in geometry than on account of a change in a specific electrical resistance on an occasion of an extension in a current flow direction.

20. The circuit as claimed in claim 17, wherein the extension sensor comprises a stress sensor, wherein a mechanical extension of the substrate is determinable on a basis of an output signal of the stress sensor.

21. The circuit as claimed in claim 17, wherein the output signal of the bridge circuit is combined with the signal through addition or subtraction.

22. The circuit as claimed in claim 17, wherein the signal is normalized to the output signal of the bridge circuit by the bridge circuit and the extension sensor being operated with a same supply voltage.

23. The circuit as claimed in claim 17, wherein dominant current flow directions of the at least two MR elements are rotated by approximately 22.5 degrees relative to edges of the substrate.

24. A method for reducing an offset drift of a bridge circuit, wherein the bridge circuit comprises at least two MR elements arranged on, at or in a substrate, wherein an extension sensor is provided which provides a signal on a basis of a difference in mechanical extensions in two different directions parallel to a plane in which the at least two MR elements lie, the method comprising:
receiving an output signal of the bridge circuit;
receiving the signal provided by the extension sensor, and
combining the output signal of the bridge circuit with the signal provided by the extension sensor.
